(19) United States
(12) Patent Application Publication
(10) Pub. No.: US 2019/0013421 A1
(43) Pub. Date: Jan. 10, 2019

(54) COMPOSITION FOR FORMING SOLAR CELL ELECTRODE AND ELECTRODE PREPARED USING THE SAME

(71) Applicant: SAMSUNG SDI CO., LTD., Yongin-si (KR)

(72) Inventors: Hyun Jin KOO, Suwon-si (KR); Min Jae KIM, Suwon-si (KR); Young Ki PARK, Suwon-si (KR); Seok Hyun JUNG, Suwon-si (KR); Gun Young HEO, Suwon-si (KR)

(21) Appl. No.: 15/950,625

(22) Filed: Apr. 11, 2018

(30) Foreign Application Priority Data
Jul. 6, 2017 (KR) 10-2017-0086149

(51) Int. Cl. H01L 31/0224; H01B 1/16

(52) U.S. Cl. CPC H01L 31/022425; H01B 1/16

(57) ABSTRACT

A composition for solar cell electrodes includes a conductive powder, a glass frit containing bismuth (Bi), tellurium (Te), and molybdenum (Mo), and an organic vehicle. The glass frit has a molar ratio of bismuth (Bi) to tellurium (Te) of about 1:7 to about 1:800 and contains about 0.1 mol % to about 40 mol % of molybdenum (Mo).

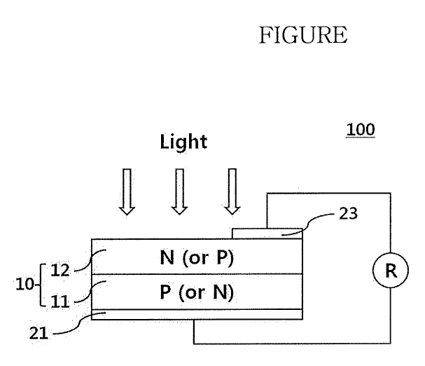

### CROSS-REFERENCE TO RELATED APPLICATION

Korean Patent Application No. 10-2017-0086149, filed on Jul. 6, 2017, in the Korean Intellectual Property Office, and entitled: “Composition for Forming Solar Cell Electrode and Electrode Prepared Using the Same,” is incorporated by reference herein in its entirety.

### BACKGROUND

### 1. Field

Embodiments relate to a composition for solar cell electrodes and an electrode fabricated using the same.

### 2. Description of the Related Art

Solar cells generate electricity using the photovoltaic effect of a p-n junction which converts photons of sunlight into electricity. In a solar cell, front and rear electrodes are formed on upper and lower surfaces of a semiconductor wafer or substrate having a p-n junction, respectively. Then, the photovoltaic effect at the p-n junction is induced by sunlight entering the semiconductor wafer and electrons generated by the photovoltaic effect at the p-n junction provide electric current to the outside through the electrodes. The electrodes of the solar cell are formed on the wafer by applying, patterning, and baking an electrode composition.

### SUMMARY

Embodiments are directed to a composition for solar cell electrodes, the composition including a conductive powder, a glass frit containing bismuth (Bi), tellurium (Te), and molybdenum (Mo), and an organic vehicle. The glass frit has a molar ratio of bismuth (Bi) to tellurium (Te) of about 1:7 to about 1:800 and contains about 0.1 mol % to about 40 mol % of molybdenum (Mo).

A total amount of bismuth (Bi) and tellurium (Te) in the glass frit may range from about 25 mol % to about 75 mol %.

A molar ratio of bismuth (Bi) to tellurium (Te) in the glass frit may be about 1:7.5 to about 1:70.

The glass frit may contain about 1 mol % to about 10 mol % of molybdenum (Mo).

The glass frit may contain about 25 mol % to about 70 mol % of the tellurium (Te), and about 1 mol % to about 40 mol % of the molybdenum (Mo).

The glass frit may further contain at least one of lead (Pb), zinc (Zn), lithium (Li), sodium (Na), phosphorus (P), germanium (Ge), gallium (Ga), cerium (Ce), iron (Fe), silicon (Si), tungsten (W), magnesium (Mg), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B).

The may include about 60 wt % to about 95 wt % of the conductive powder, about 0.1 wt % to about 20 wt % of the glass frit, and about 1 wt % to about 30 wt % of the organic vehicle.

The composition may include at least one additive selected from a dispersant, a thixotropic agent, a plasticizer, a viscosity stabilizer, an anti-foaming agent, a pigment, a UV stabilizer, an antioxidant, and a coupling agent.

A solar cell electrode may be fabricated using the composition.

### BRIEF DESCRIPTION OF THE DRAWING

Features will become apparent to those of skill in the art by describing in detail exemplary embodiments with reference to the attached drawing in which:

The FIGURE illustrates a schematic view of a solar cell according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

In construing elements of embodiments, it is regarded to include an error range even though there is no distinctive description.

As used herein, the term “metal oxide” refers to a single metal oxide or a plurality of metal oxides.

Further, ‘X to Y’, as used herein to represent a range of a certain value means ‘more than or equal to X and less than or equal to Y’.

Herein, the content (mol %) of each elemental metal included in a glass frit may be measured by inductively coupled plasma-optical emission spectrometry (ICP-OES). For example, ICP-OES may include pre-treating a sample, preparing a standard solution, and calculating the content of each elemental metal in the sample by measuring and converting the concentration of an analysis target. In operation of pre-treating a sample, a predetermined amount of the sample may be dissolved in an acid solution and then heated for carbonization. The acid solution may include, for example, a sulfuric acid (H₂SO₄) solution. The carbonized sample may be diluted with a solvent such as distilled water or hydrogen peroxide (H₂O₂) to an appropriate extent that allows analysis of the analysis target. In view of element detection capability of an ICP-OES tester, the carbonized sample may be diluted about 10,000 fold. In measurement with the ICP-OES tester, the pre-treated sample may be calibrated using a standard solution, for example, an analysis target standard solution for measuring elements. By way of example, calculation of the mole content of each element in the glass frit can be accomplished by introducing the standard solution into the ICP-OES tester and plotting a calibration curve using an external standard method, followed by measuring and converting the concentration (ppm) of each elemental metal in the pre-treated sample using the ICP-OES tester.

Composition for Solar Cell Electrodes

A composition for solar cell electrodes includes a conductive powder, a glass frit containing bismuth (Bi), tellurium (Te), and molybdenum (Mo), and an organic vehicle, wherein the glass frit has a molar ratio of bismuth (Bi) to tellurium (Te) of about 1:7 to about 1:800 and contains about 0.1 mol % to about 40 mol % of molybdenum (Mo).

Now, each component of the composition for solar cell electrodes according embodiments will be described in more detail.

Conductive Powder

The conductive powder may serve to impart electrical conductivity to the composition for solar cell electrodes. The composition for solar cell electrodes according to embodiments may include a metal powder such as silver (Ag) powder or aluminum (Al) powder as the conductive powder. For example, the conductive powder may be silver powder. The conductive powder may have a nanometer or micrometer-scale particle size. For example, the conductive powder may be silver powder having a particle diameter of dozens to several hundred nanometers or having a particle diameter of several to dozens of micrometers. In some implementations, the conductive powder may be a mixture of two or more types of silver powder having different particle sizes.

The conductive powder may have a suitable particle shape such as a spherical, flake or amorphous particle shape.

The conductive powder may have an average particle diameter (D50) of about 0.1 μm to about 10 μm, or, for example, about 0.5 μm to about 5 μm. Within this range of average particle diameter, the composition can reduce contact resistance and line resistance of a solar cell. The average particle diameter may be measured using, for example, a Model 1064D particle size analyzer (CILAS Co., Ltd.) after dispersing the conductive powder in isopropyl alcohol (IPA) at 25° C. for 3 minutes via ultrasonication.

The conductive powder may be present in an amount of about 60 wt % to about 95 wt %, or, for example, about 70 wt % to about 90 wt % in the composition for solar cell electrodes. Within this range, the composition can improve conversion efficiency of a solar cell and can be easily prepared in paste form. For example, the conductive powder may be present in an amount of about 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt % in the composition for solar cell electrodes.

Glass Frit

The glass frit may serve to form silver crystal grains in an emitter region by etching an anti-reflection layer and melting the conductive powder during a baking process of the composition for solar cell electrodes. The glass frit may improve adhesion of the conductive powder to a wafer and may become softened to decrease the baking temperature during the baking process.

The glass frit contains bismuth (Bi), tellurium (Te), and molybdenum (Mo), wherein a molar ratio of bismuth (Bi) to tellurium (Te) ranges from about 1:7 to about 1:800 and wherein molybdenum (Mo) is present in an amount of about 0.1 mol % to about 40 mol % in the glass frit.

When the molar ratio of bismuth (Bi) to tellurium (Te) ranges from about 1:7 to about 1:800, the composition for solar cell electrodes may be easily formed into an electrode. For example, the composition have good moldability, while improving the aspect ratio of the electrode. The glass frit may have a molar ratio of bismuth (Bi) to tellurium (Te) of, for example, about 1:7.5 to about 1:70.

When molybdenum (Mo) is present in an amount of about 0.1 mol % to about 40 mol % in the glass frit, the glass frit may improve an open-circuit voltage (Voc) without reduction in serial resistance (Rs). Molybdenum (Mo) may be present in an amount of, for example, about 1 mol % to about 10 mol % in the glass frit.

In addition, a total amount of bismuth (Bi) and tellurium (Te) in the glass frit may range from about 25 mol % to about 75 mol %, or, for example, about 35 mol % to about 70 mol %, or, for example, about 56 mol % to about 66 mol %. Within these ranges, the glass frit may prevent spreading of an electrode during baking of the composition for solar cell electrodes, such that the electrode may have a high aspect ratio. For example, a total amount of bismuth (Bi) and tellurium (Te) in the glass frit may be about 25 mol %, 26 mol %, 27 mol %, 28 mol %, 29 mol %, 30 mol %, 31 mol %, 32 mol %, 33 mol %, 34 mol %, 35 mol %, 36 mol %, 37 mol %, 38 mol %, 39 mol %, 40 mol %, 41 mol %, 42 mol %, 43 mol %, 44 mol %, 45 mol %, 46 mol %, 47 mol %, 48 mol %, 49 mol %, 50 mol %, 51 mol %, 52 mol %, 53 mol %, 54 mol %, 55 mol %, 56 mol %, 57 mol %, 58 mol %, 59 mol %, 60 mol %, 61 mol %, 62 mol %, 63 mol %, 64 mol %, 65 mol %, 66 mol %, 67 mol %, 68 mol %, 69 mol %, 70 mol %, 71 mol %, 72 mol %, 73 mol %, 74 mol %, or 75 mol %.

The glass frit may contain about 0.05 mol % to about 35 mol % of bismuth (Bi), about 25 mol % to about 70 mol % of tellurium (Te), and about 1 mol % to about 40 mol % of molybdenum (Mo). Within this range, the glass frit may improve the aspect ratio of an electrode while enhancing electrical properties of the electrode such as open-circuit voltage (Voc) and serial resistance (Rs). The glass frit may contain, for example, about 0.6 mol % to about 30 mol %, or, for example, about 1 mol % to about 10 mol % of bismuth (Bi) and about 45 mol % to about 70 mol %, or, for example, about 50 mol % to about 66 mol % of tellurium (Te).

For example, the glass frit may contain bismuth (Bi) in an amount of about 0.05 wt %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt % or 35 wt %.

The glass frit may contain tellurium (Te) in an amount of, for example, about 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, or 70 wt %.

The glass frit may contain molybdenum (Mo) in an amount of, for example, about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, or 40 wt %.

The glass frit may further include at least one of lead (Pb), zinc (Zn), lithium (Li), sodium (Na), phosphorus (P), germanium (Ge), gallium (Ga), cerium (Ce), iron (Fe), silicon (Si), tungsten (W), magnesium (Mg), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B).

For example, the glass frit may further comprise at least one of lithium (Li), silicon (Si), zinc (Zn), and manganese (Mn).

The glass frit may be prepared by a suitable method. For example, the glass frit may be prepared by mixing the aforementioned components using a ball mill or a planetary mill, melting the mixture at about 900° C. to about 1300° C., and quenching the melted mixture to 25° C., followed by pulverizing the obtained product using a disk mill, a planetary mill or the like.

The glass frit may be present in an amount of about 0.1 wt % to about 20 wt %, or, for example, about 0.5 wt % to about 10 wt % in the composition for solar cell electrodes. Within these ranges, the glass frit may secure stability of a p-n junction under various sheet resistances, minimize resistance, and ultimately improve the efficiency of a solar cell. For example, the glass frit may be present in an amount of about 0.1 wt %, 0.5 wt %, 1 wt %, 1.5 wt %, 2 wt %, 2.5 wt %, 3 wt %, 3.5 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt % in the composition for solar cell electrodes.

Organic Vehicle

The organic vehicle may impart suitable viscosity and rheological characteristics for printing to the composition for solar cell electrodes through mechanical mixing with inorganic components of the composition.

The organic vehicle may be a suitable organic vehicle used in a composition for solar cell electrodes. The organic vehicle may include a binder resin, a solvent, or the like.

The binder resin may be selected from acrylate resins or cellulose resins. For example, ethyl cellulose may be used as the binder resin. In some implementations, the binder resin may be selected from among ethyl hydroxyethyl cellulose, nitrocellulose, blends of ethyl cellulose and phenol resins, alkyd resins, phenol resins, acrylate ester resins, xylene resins, polybutane resins, polyester resins, urea resins, melamine resins, vinyl acetate resins, wood rosin, polymethacrylates of alcohols, or the like.

The solvent may be selected from, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, or ethyl lactate. These may be used alone or as a mixture thereof.

The organic vehicle may be present in an amount of about 1 wt % to about 30 wt % in the composition for solar cell electrodes. Within this range, the organic vehicle may provide sufficient adhesive strength and good printability to the composition. For example, the organic vehicle may be present in an amount of about 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt % in the composition for solar cell electrodes.

Additives

The composition for solar cell electrodes according to embodiments may further include a suitable additive to enhance fluidity, process properties and stability, as desired. The additive may include a dispersant, a thixotropic agent, a plasticizer, a viscosity stabilizer, an anti-foaming agent, a pigment, a UV stabilizer, an antioxidant, a coupling agent, or the like. These may be used alone or as mixtures thereof. The additive may be present in an amount of about 0.1 wt % to about 5 wt % based on the total weight of the composition for solar cell electrodes, although the content of the additive may be varied, as desired. For example, the additive may be present in an amount of about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 1.5 wt %, 2 wt %, 2.5 wt %, 3 wt %, 3.5 wt %, 4 wt %, 4.5 wt %, or 5 wt % based on the total weight of the composition for solar cell electrodes.

Solar Cell Electrode and Solar Cell Including the Same

Embodiments further relate to an electrode formed of the composition for solar cell electrodes and a solar cell including the same. The FIGURE illustrates a solar cell in accordance with an embodiment.

Referring to the FIGURE, a solar cell 100 may include a substrate 10, a front electrode 23 formed on a front surface of the substrate 10, and a rear electrode 21 formed on a back surface of the substrate 10.

The substrate 10 may be a substrate with a p-n junction formed thereon. For example, the substrate 10 may include a semiconductor substrate 11 and an emitter 12. The substrate 10 may be a substrate prepared by doping one surface of a p-type semiconductor substrate 11 with an n-type dopant to form an n-type emitter 12. In some implementations, the substrate 10 may be a substrate prepared by doping one surface of an n-type semiconductor substrate 11 with a p-type dopant to form a p-type emitter 12. The semiconductor substrate 11 may be either a p-type substrate or an n-type substrate. The p-type substrate may be a semiconductor substrate 11 doped with a p-type dopant, and the n-type substrate may be a semiconductor substrate 11 doped with an n-type dopant.

In description of the substrate 10, the semiconductor substrate 11, or the like, a surface of such a substrate through which light enters the substrate is referred to as a “front surface” (light receiving surface). In addition, a surface of the substrate opposite the front surface is referred to as a “back surface”.

In an embodiment, the semiconductor substrate 11 may be formed of crystalline silicon or a compound semiconductor. Here, the crystalline silicon may be monocrystalline or polycrystalline. As an example of the crystalline silicon, a silicon wafer may be used.

The p-type dopant may be a material that includes a group III element such as boron, aluminum, or gallium. The n-type dopant may be a material that includes a group V element, such as phosphorus, arsenic or antimony.

The front electrode 23 and/or the rear electrode 21 may be fabricated using the composition for solar cell electrodes according to embodiments. For example, the front electrode 23 may be fabricated using the composition including silver powder as the conductive powder, and the rear electrode 21 may be fabricated using the composition including aluminum powder as the conductive powder. The front electrode 23 may be formed by printing the composition for solar cell electrodes onto the emitter 12, followed by baking, and the rear electrode 21 may be formed by applying the composition for solar cell electrodes to the back surface of the semiconductor substrate 11, followed by baking.

Next, embodiments will be described in more detail with reference to examples. The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

As an organic binder, 3.0 wt % of ethylcellulose (STD4, Dow Chemical Company) was sufficiently dissolved in 6.5 wt % of butyl carbitol at 60° C., and then 86.9 wt % of spherical silver powder (AG-4-8, Dowa Hightech Co., Ltd.) having an average particle diameter of 2.0 μm, 3.1 wt % of a glass frit having an average particle diameter of 1.0 μm and containing elemental metals in amounts as listed in Table 1, 0.2 wt % of a dispersant BYK102 (BYK-chemie), and 0.3 wt % of a thixotropic agent Thixatrol ST (Elementis Co., Ltd.) were added to the binder solution, followed by mixing and kneading in a 3-roll kneader, thereby preparing a composition for solar cell electrodes.

### Examples 2 to 7 and Comparative Examples 1 to 7

A composition for solar cell electrodes was prepared in the same manner as in Example 1 except that glass frits described in Table 1 were used.

TABLE 1

| | | | | | | | | | | | Molar ratio |
|---|---|---|---|---|---|---|---|---|---|---|---|
| | Bi | Te | Mo | Li | Si | Zn | Mg | Cr | Al | Total | Bi:Te |
| Example 1 | 3 | 56 | 4 | 20 | 3 | 10 | 4 | — | — | 100 | 1:18.7 |
| Example 2 | 8 | 56 | 4 | 15 | 3 | 10 | 4 | — | — | 100 | 1:7 |
| Example 3 | 0.8 | 56 | 4 | 22.2 | 3 | 10 | 4 | — | — | 100 | 1:70 |
| Example 4 | 0.07 | 56 | 4 | 22.93 | 3 | 10 | 4 | — | — | 100 | 1:800 |
| Example 5 | 3 | 65 | 1 | 14 | 3 | 10 | 4 | — | — | 100 | 1:21.7 |
| Example 6 | 3 | 58 | 8 | 14 | 3 | 10 | 4 | — | — | 100 | 1:19.3 |
| Example 7 | 3 | 26 | 40 | 14 | 3 | 10 | 4 | — | — | 100 | 1:8.7 |
| Comp. Example 1 | 10 | 53 | 4 | 16 | 3 | 10 | 4 | — | — | 100 | 1:5.3 |
| Comp. Example 2 | 0.05 | 62.95 | 4 | 16 | 3 | 10 | 4 | — | — | 100 | 1:1259 |
| Comp. Example 3 | 5 | 67.95 | 0.05 | 10 | 3 | 10 | 4 | — | — | 100 | 1:13.6 |
| Comp. Example 4 | 0.5 | 27.5 | 45 | 10 | 3 | 10 | 4 | — | — | 100 | 1:55 |
| Comp. Example 5 | 3 | 56 | — | 20 | 3 | 10 | 4 | 4 | — | 100 | 1:18.7 |
| Comp. Example 6 | 3 | 56 | — | 20 | 3 | 10 | 4 | — | 4 | 100 | 1:18.7 |
| Comp. Example 7 | 12 | 68.5 | 0.5 | 7 | 3 | 5 | 4 | — | — | 100 | 1:5.7 |

(unit: mol %)

Property Evaluation

(1) Contact Resistance (Rc, Unit: mΩ), Serial Resistance (Rs, Unit: mΩ), Open-Circuit Voltage (Voc, Unit: mV):

Each composition for solar cell electrodes prepared in Examples and Comparative Examples was deposited onto a front surface of a wafer by screen printing in a predetermined pattern, followed by drying in an IR drying furnace. A cell formed according to this procedure was subjected to baking at 600° C. to 900° C. for 60 to 210 seconds in a belt-type baking furnace, and then evaluated as to contact resistance (Rc), serial resistance (Rs), and open-circuit voltage (Voc) using a TLM (Transfer Length Method) tester. Results are shown in Table 2.

(2) Fill Factor (%) and Efficiency (%):

Each composition for solar cell electrodes prepared in Examples and Comparative Examples was deposited onto a front surface of a wafer by screen printing in a predetermined pattern, followed by drying in an IR drying furnace. Then, an aluminum paste was printed onto a back surface of the wafer and dried in the same manner as above. A cell formed according to this procedure was subjected to baking at 400° C. to 900° C. for 30 to 180 seconds in a belt-type baking furnace, and then evaluated as to fill factor (FF, %) and conversion efficiency (Eff. %) using a solar cell efficiency tester CT-801 (Pasan Co., Ltd.). Results are shown in Table 2.

(3) Linewidth (μm), Thickness (μm), Aspect Ratio:

A printing mask (Sanli Precision Ind.) having an opening rate of 82% and an electrode pattern linewidth of 26 μm was placed on a semiconductor substrate, and then each composition for solar cell electrodes prepared in Examples and Comparative Examples was placed on the printing mask, followed by drying in an IR drying furnace subsequent to printing the composition onto the semiconductor substrate through squeezing. Then, an aluminum paste was printed onto a back surface of the semiconductor substrate and dried in the same manner as above. A cell formed according to this procedure was subjected to baking at 950° C. for 45 seconds in a belt-type baking furnace, thereby obtaining a solar cell.

The linewidth, thickness, and aspect ratio of the electrodes of the obtained solar cells were measured using a three-dimensional measuring instrument (VK Analyzer, KEYENCE Corporation). Results are shown in Table 2.

TABLE 2

| | Contact | Serial | | | | | | |
|---|---|---|---|---|---|---|---|---|
| | resistance | resistance | Open-circuit | | Eff. | Linewidth | Thickness | Aspect |
| | (mΩ) | (mΩ) | voltage (mV) | FF (%) | (%) | (μm) | (μm) | ratio |
| Example 1 | 0.225 | 2.59 | 642.47 | 79.18 | 18.24 | 51.458 | 17.561 | 0.341 |
| Example 2 | 0.247 | 2.62 | 643.14 | 78.99 | 18.20 | 57.694 | 16.852 | 0.292 |
| Example 3 | 0.271 | 2.80 | 642.76 | 78.94 | 18.22 | 48.023 | 17.358 | 0.361 |
| Example 4 | 0.308 | 2.96 | 642.55 | 78.92 | 18.17 | 47.578 | 17.021 | 0.358 |
| Example 5 | 0.310 | 2.96 | 640.22 | 78.92 | 18.16 | 59.368 | 16.911 | 0.285 |
| Example 6 | 0.299 | 2.85 | 642.75 | 78.93 | 18.20 | 56.487 | 16.898 | 0.299 |
| Example 7 | 0.318 | 3.04 | 639.77 | 78.92 | 18.14 | 52.658 | 16.687 | 0.317 |
| Comparative | 0.325 | 3.05 | 639.66 | 78.88 | 18.10 | 61.587 | 16.325 | 0.265 |
| Example 1 | | | | | | | | |
| Comparative | 0.340 | 3.09 | 639.39 | 78.86 | 18.09 | 60.878 | 16.854 | 0.277 |
| Example 2 | | | | | | | | |
| Comparative | 0.339 | 3.08 | 639.47 | 78.88 | 18.10 | 64.221 | 16.321 | 0.254 |
| Example 3 | | | | | | | | |
| Comparative | 0.431 | 3.50 | 633.36 | 78.11 | 17.85 | 62.328 | 16.574 | 0.266 |
| Example 4 | | | | | | | | |
| Comparative | 0.432 | 3.55 | 633.11 | 77.82 | 17.83 | 50.214 | 17.436 | 0.347 |
| Example 5 | | | | | | | | |
| Comparative | 0.552 | 3.68 | 631.67 | 77.78 | 17.80 | 51.087 | 17.532 | 0.343 |
| Example 6 | | | | | | | | |
| Comparative | 0.398 | 3.41 | 635.88 | 78.31 | 17.90 | 71.587 | 15.932 | 0.223 |
| Example 7 | | | | | | | | |

As shown in Table 2, it can be seen that the solar cell electrode fabricated using a composition for solar cell electrodes according to embodiments in which the molar ratio of bismuth to tellurium and the content (mol %) of molybdenum fell within the ranges set forth herein exhibited improved open-circuit voltage without an increase in resistance while having a high aspect ratio.

Conversely, the solar cell electrodes of Comparative Examples 1 and 2, in which the molar ratio of bismuth to tellurium was outside the range set forth herein, exhibited high contact resistance and serial resistance and low open-circuit voltage. The solar cell electrodes of Comparative Examples 3 to 4, in which the content of molybdenum was outside the range set forth herein, had a low aspect ratio while exhibiting considerably high contact resistance or poor fill factor and conversion efficiency. The solar cell electrodes of Comparative Examples 5 to 6, which were free from molybdenum, exhibited high contact resistance and serial resistance.

By way of summation and review, as an electrode composition, a conductive paste composition including a conductive powder, a glass frit, and an organic vehicle is used. The glass frit serves to melt an anti-reflection film on a semiconductor wafer, thereby establishing electrical contact between the conductive powder and the wafer.

Particularly, the glass frit affects not only electrical characteristics of a solar cell, such as open-circuit voltage (Voc) and serial resistance (Rs) of an electrode formed of the electrode composition, but also an aspect ratio of the electrode upon which conversion efficiency and fill factor of the solar cell depend.

Therefore, a composition for solar cell electrodes which can improve an aspect ratio of an electrode formed thereof as well as electrical characteristics of the electrode, such as open-circuit voltage (Voc) and serial resistance (Rs) is desirable.

Embodiments provide a composition for solar cell electrodes that can improve an aspect ratio of an electrode formed thereof as well as electrical characteristics of the electrode, such as open-circuit voltage (Voc) and serial resistance (Rs), and an electrode fabricated using the same. Conversion efficiency and fill factor of a solar cell may be thereby improved. An electrode may be fabricated using the composition.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A composition for solar cell electrodes, the composition comprising:
a conductive powder;
a glass frit containing bismuth (Bi), tellurium (Te), and molybdenum (Mo); and
an organic vehicle,
wherein the glass frit has a molar ratio of bismuth (Bi) to tellurium (Te) of about 1:7 to about 1:800 and contains about 0.1 mol % to about 40 mol % of molybdenum (Mo).

2. The composition as claimed in claim 1, wherein a total amount of bismuth (Bi) and tellurium (Te) in the glass frit ranges from about 25 mol % to about 75 mol %.

3. The composition as claimed in claim 1, wherein a molar ratio of bismuth (Bi) to tellurium (Te) in the glass frit is about 1:7.5 to about 1:70.

4. The composition as claimed in claim 1, wherein the glass frit contains about 1 mol % to about 10 mol % of molybdenum (Mo).

5. The composition as claimed in claim 1, wherein the glass frit contains about 0.05 mol % to about 35 mol % of the bismuth (Bi), about 25 mol % to about 70 mol % of the tellurium (Te), and about 1 mol % to about 40 mol % of the molybdenum (Mo).

6. The composition as claimed in claim 1, wherein the glass frit further contains at least one of lead (Pb), zinc (Zn), lithium (Li), sodium (Na), phosphorus (P), germanium (Ge), gallium (Ga), cerium (Ce), iron (Fe), silicon (Si), tungsten (W), magnesium (Mg), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B).

7. The composition as claimed in claim 1, comprising:
about 60 wt % to about 95 wt % of the conductive powder;
about 0.1 wt % to about 20 wt % of the glass frit; and
about 1 wt % to about 30 wt % of the organic vehicle.

8. The composition as claimed in claim 1, further comprising at least one additive selected from among a dispersant, a thixotropic agent, a plasticizer, a viscosity stabilizer, an anti-foaming agent, a pigment, a UV stabilizer, an antioxidant, and a coupling agent.

9. A solar cell electrode fabricated using the composition for solar cell electrodes as claimed in claim 1.
